(19) United States
(12) Patent Application Publication
(10) Pub. No.: US 2007/0054158 A1
(43) Pub. Date: Mar. 8, 2007

(54) Combination of photovoltaic devices and batteries which utilize a solid polymeric electrolyte

(76) Inventors: Stanford R. Ovshinsky, Bloomfield, MI (US); Boyko Aladjov, Rochester Hills, MI (US); Meera Vijan, West Bloomfield, MI (US)

Correspondence Address: ENERGY CONVERSION DEVICES, INC., 2956 WATERVIEW DRIVE, ROCHESTER HILLS, MI, 48309, US

(21) Appl. No.: 11/328,531

(22) Filed: Jan. 10, 2006

Related U.S. Application Data
(63) Continuation-in-part of application No. 11/220,937, filed on Sep. 7, 2005.

(51) Int. Cl. H01M 16/00; H01M 4/48; H01M 4/52; H01L 31/00

(52) U.S. Cl. 429/9; 429/223; 429/231.6; 429/218.1; 429/221; 429/218.2; 429/316; 136/261

(57) ABSTRACT

A combination of photovoltaic devices and solid state batteries. The solid state battery comprising at least one negative electrode which may include a metal hydride active material, at least one positive electrode including an active material, and an anionic exchange membrane disposed between said negative electrode and said positive electrode. The anionic exchange membrane may be selected from materials allowing the flow of hydroxyl ions therethrough while simultaneously electrically separating the positive and negative electrodes. The anionic exchange membrane may be selected from a number of different materials based on different chemistries which allow the flow of hydroxyl ions therethrough. The anionic exchange membrane may be comprised of a polystyrene-divinylbenzene-polyvinylchloride polymeric material. The photovoltaic devices may be amorphous silicon solar cells. The photovoltaic devices may be triple junction, tandem amorphous silicon solar cells. The photovoltaic devices may be in the form of a roofing material. The photovoltaic devices may be deposited on thin film plastic material such as Kapton.

### CONTINUING APPLICATION INFORMATION

This application is a continuation in part of U.S. Application Serial number 11/220,937 filed Sep. 7, 2005.

### FIELD OF THE INVENTION

The present invention generally relates to a combination of photovoltaic devices and rechargeable electrochemical cells. More particularly, the present invention relates to a combination of photovoltaic devices and batteries utilizing non-liquid electrolytes. Most specifically the present invention relates to a combination of photovoltaic devices and a new category of batteries using non-aqueous anionic exchange membranes as the electrolyte.

### BACKGROUND

Photovoltaic energy is becoming a very significant source of electrical power. This is because problems of scarcity and safety have limited the use of fossil and nuclear fuels, and recent advances in photovoltaic technology have made possible the large scale manufacture of low cost, lightweight, thin film photovoltaic devices. It is now possible to manufacture large scale, thin film silicon and/or germanium alloy materials which manifest electrical and optical properties equivalent, and in many instances superior to, their single crystal counterparts. These alloys can be economically deposited at high speed over relatively large areas and in a variety of device configurations, and as such they readily lend themselves to the manufacture of low cost, large area photovoltaic devices. U.S. Pat. Nos. 4,226,898 and 4,217,374 both disclose particular thin film alloys having utility in the manufacture of photovoltaic devices of the type which may be employed in the present invention. However, it is to be understood that the present invention is not limited to any particular class of photovoltaic materials and may be practiced with a variety of semiconductor materials including crystalline, polycrystalline, microcrystalline, and noncrystalline materials.

To be useful, photovoltaic devices need a system to store excess energy created when energy creation by the photovoltaic devices is greater than the energy demand (for example during sunny daylight hours), for subsequent use when the energy demand is greater than the energy creation by the photovoltaic devices (for example at night or on cloudy days). Typically the energy storage systems used to store this excess energy have used large, heavy, aqueous electrolyte batteries such as lead-acid batteries, nickel-cadmium batteries and nickel-metal hydride batteries. For consumer use where the photovoltaic devices are mounted on the roof these battery systems cannot be mounted on the roofs. Thus the storage batteries for the system are placed at a distance from the photovoltaic devices. This takes up additional space is some other part of the building on which the photovoltaic devices are mounted.

Also, when flexible, portable photovoltaic devices are used, they can generally be rolled or folded to reduce the size during non-use transport. However, the batteries which are conventionally used in conjunction with the portable photovoltaic devices are not able to be stowed as easily as the folded portable photovoltaic devices.

With the growth of technology and the need for smaller more compact sources of power, solid state batteries are gaining attention for a wide variety of applications. Solid state batteries are lightweight and durable. Solid state batteries can be the size of a credit card, or smaller while still being able to power a number of devices. The size and weight of solid state batteries allows them to be taken anywhere without the need to worry about size and weight limitations. Solid state batteries may be used for consumer electronics, medical devices, miniature power devices, tracking systems, space applications, survival kits, etc. Solid state batteries are anticipated to have performance and overall cycle life benefits over conventional battery technology.

Presently, most of the work being performed on solid state batteries is related to lithium ions batteries, as lithium ion batteries are a preferred source of power for a number of end-user applications. Even though lithium ion batteries are widely used as a source of power for a number of end-user applications, they still have a number of disadvantages. Lithium ion batteries require special controls to prevent overcharge/overdischarge which can lead to overheating and/or damage to the lithium ion battery unit. In certain instances, overheating of lithium ion batteries has caused the batteries to catch fire and/or explode. Lithium ion batteries also have a much more restricted operating temperature range than some other types of batteries such as nickel metal hydride batteries. Lithium ion batteries have shown poor performance at both high and low temperatures. Lithium ion batteries also require special sealing to prevent the lithium from reacting with moisture and/or oxygen which may cause the battery to catch fire and/or explode. Also, lithium ion batteries are not capable of delivering high current discharge output.

Nickel metal hydride batteries have a number of advantages over lithium ion batteries. Nickel metal hydride batteries do not require complex control systems to prevent overcharging/overdischarging of the battery units. Nickel metal hydride batteries also have a significantly broader operating temperature range allowing the battery units to perform in extreme temperatures. Nickel metal hydride batteries are also less expensive than lithium ion batteries.

Nickel metal hydride batteries typically include a nickel hydroxide positive electrode, a negative electrode that incorporates a hydrogen storage alloy, a separator and an aqueous alkaline electrolyte. The positive and negative electrodes are housed in adjoining battery compartments that are typically separated by a non-woven, felled, nylon, polyethylene, or polypropylene separator. Several batteries may also be combined in series to form larger battery packs capable of providing higher powers, voltages or discharge rates.

In general, nickel-metal hydride (Ni-MH) cells utilize a negative electrode comprising a metal hydride active material that is capable of the reversible electrochemical storage of hydrogen. The positive electrode of the nickel-metal hydride cell comprises a nickel hydroxide active material. The negative and positive electrodes are spaced apart from one another and separated by a separator containing an alkaline electrolyte.

Upon application of an electrical current across a Ni-MH cell, the Ni-MH material of the negative electrode is charged by the absorption of hydrogen formed by electrochemical water discharge reaction and the electrochemical generation of hydroxyl ions: 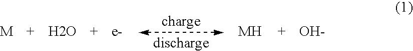
The negative electrode reactions are reversible. Upon discharge, the stored hydrogen is released to form a water molecule and release an electron.

The charging process for a nickel hydroxide positive electrode in an alkaline electrochemical cell is governed by the following reaction:

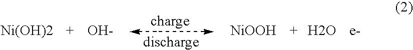

After the first charge of the electrochemical cell, the nickel hydroxide is oxidized to form nickel oxyhydroxide. During discharge of the electrochemical cell, the nickel oxyhydroxide is reduced to form beta nickel hydroxide as shown by the following reaction:

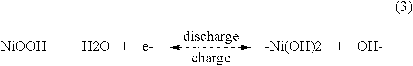

Much work has been completed over the past decade to improve the performance of nickel metal hydride batteries. Optimization of the batteries ultimately depends on controlling the rate, extent and efficiency of the charging and discharging reactions. Factors relevant to battery performance include the physical state, surface area and morphology, chemical composition, catalytic activity and other properties of the positive and negative electrode materials, the composition and concentration of the electrolyte, materials used as the separator, the operating conditions, and external environmental factors.

Work on suitable negative electrode materials has focused on intermetallic compounds such as hydrogen storage alloys since the late 1950's when it was determined that the compound TiNi reversibly absorbed and desorbed hydrogen. Subsequent work has shown that intermetallic compounds having the general formulas AB, AB₂ A2_{B} and AB₅, where A is a hydride forming element and B is a weak or non-hydride forming element, are able to reversibly absorb and desorb hydrogen. Consequently, most of the effort in developing negative electrodes has focused on hydrogen storage alloys having the AB, AB₂, AB₅ or A₂B formula types.

Desirable properties of hydrogen storage alloys include: good hydrogen storage capabilities to achieve a high energy density and high battery capacity; thermodynamic properties suitable for the reversible absorption and desorption of hydrogen; low hydrogen equilibrium pressure; high electrochemical activity; fast discharge kinetics for high rate performance; high oxidation resistance; high resistance to cell self-discharge; and reproducible performance over many cycles.

There is a need for solid state technology to be applied to nickel metal hydride and other chemistry batteries and for a combination of photovoltaic devices with such solid state batteries.

### SUMMARY OF THE INVENTION

Disclosed herein, is a combination of photovoltaic devices and solid state batteries. The solid state battery comprising at least one negative electrode which may include a metal hydride active material, at least one positive electrode including an active material, and an anionic exchange membrane disposed between said negative electrode and said positive electrode. The anionic exchange membrane may be selected from materials allowing the flow of hydroxyl ions therethrough while simultaneously electrically separating the positive and negative electrodes. The anionic exchange membrane may be selected from a number of different materials based on different chemistries which allow the flow of hydroxyl ions therethrough. The anionic exchange membrane may be comprised of a polystyrene-divinylbenzene-polyvinylchloride polymeric material. The photovoltaic devices may be amorphous silicon solar cells. The photovoltaic devices may be triple junction, tandem amorphous silicon solar cells. The photovoltaic devices may be in the form of a roofing material. The photovoltaic devices may be deposited on thin film plastic material such as Kapton.

### BRIEF DESCRIPTION OF THE DRAWINGS

FIG. 1, is a depiction of a nickel metal hydride battery in accordance with the present invention;

FIG. 2, is a plot of charge/discharge capacity at a constant current vs. Time for a battery in accordance with the present invention;

FIG. 3, is a plot of charge/discharge efficiency vs. cycle life for batteries in accordance with the present invention;

FIG. 4 is an exploded view of a schematic representation of one embodiment the combined photovoltaic device and solid state battery of the present invention; and

FIG. 5 is a combined view of a schematic representation of one embodiment the combined photovoltaic device and solid state battery of the present invention shown in FIG. 4.

### DETAILED DESCRIPTION OF THE PREFERRED EMBODIMENTS OF THE INVENTION

In accordance with the present invention there is provided photovoltaic devices in combination with solid state batteries utilizing solid polymeric electrolyte. The battery generally comprises one or more electrochemical cells. Each electrochemical cell comprises at least one positive electrode including an active material, at least one negative electrode including an active material, and at least one anionic exchange membrane. Each positive electrode and each negative electrode are separated by and in contact with the anionic exchange membrane.

The capacity of each sealed cell may be limited by the positive electrode, thereby allowing for oxygen recombination during overcharge. The reactions during overcharge for the positive electrode and the negative electrode for a Ni(OH)₂/MH battery are shown by the following equations:
4OH—->2H₂O+O₂+4e- (Positive electrode)
2H₂0+O₂+4e-->4OH— (Negative electrode)
Alternatively, during over discharge, hydrogen generated at the positive electrode is readily recombined at the negative electrode. The reactions during over discharge for the positive electrode and the negative electrode are shown by the following equations:
2H2O+2e-->H2+2OH— (Positive electrode)
H2+2OH—->2H20+2e- (Negative electrode)
The ability to manage overcharge and to tolerate over discharge is a unique characteristic of for example nickel metal hydride batteries making them advantageous over lithium ion batteries.

The negative electrode comprises a negative electrode active material supported on a conductive substrate. The negative electrode active material may comprise a metal hydride active material. The negative electrodes of a nickel-metal hydride battery are generally formed by applying a powdered active material into the conductive substrate. The powdered active may be applied onto the conductive substrate via a pasting or compression technique. The negative electrode may also include a conductive polymeric binder as disclosed in U.S. Pat. Ser. No. 10/329,221 to Ovshinsky et al., the disclosure of which is hereby incorporated by reference.

The negative electrode active material of the negative electrode may include an electrochemical hydrogen storage material, such as AB, AB₂, AB₅, A₂B₇, Mg—Ni, and Ca—Ni based battery type hydrogen storage alloys. In fact, any known battery metal hydride material can be used in the non-aqueous battery of the present invention. Examples are set forth hereinafter.

The hydrogen storage material may be chosen from the Ti—V—Zr—Ni active materials such as those disclosed in U.S. Pat. Nos. 4,551,400 (“the '400 patent”), the disclosure of which is incorporated by reference. As discussed above, the materials used in the '400 patent utilize a Ti—V—Ni composition, where at least Ti, V, and Ni are present with at least one or more of Cr, Zr, and Al. The materials of the '400 patent are multi-phase materials, which may contain, but are not limited to, one or more phases with C14 and C15 type crystal structures.

There are other Ti—V—Zr—Ni alloys which may also be used for the hydrogen storage material of the negative electrode. One family of materials are those described in U.S. Pat. No. 4,728,586 (“the '586 patent”), the disclosure of which is incorporated by reference. The '586 patent discloses Ti—V—Ni—Zr alloys comprising T, V, Zr, Ni, and a fifth component, Cr. The '586 patent mentions the possibility of additives and modifiers beyond the T, V, Zr, Ni, and Cr components of the alloys, and discusses other additives and modifiers, the amounts and interactions of the modifiers, and the particular benefits that could be expected from them.

In addition to the materials described above, hydrogen storage materials for the negative electrode of a NiMH battery may also be chosen from the disordered metal hydride alloy materials that are described in detail in U.S. Pat. No. 5,277,999 (“the '999 patent”), to Ovshinsky and Fetcenko, the disclosure of which is incorporated herein by reference.

Examples of Mg—Ni based battery alloys are disclosed in U.S. Pat. Nos. 5,616,432 and 5,506,069, the disclosures of which is incorporated herein by reference. These patents disclose electrochemical hydrogen storage materials comprising:

(Base Alloy)ₐ M_{b} where, Base Alloy is an alloy of Mg and Ni in a ratio of from about 1:2 to about 2:1, preferably 1:1; M represents at least one modifier element chosen from the group consisting of Co, Mn, Al, Fe, Cu, Mo, W, Cr, V, Ti, Zr, Sn, Th, Si, Zn, Li, Cd, Na, Pb, La, Mm, and Ca; b is greater than 0.5, preferably 2.5, atomic percent and less than 30 atomic percent; and a+b=100 atomic percent. Preferably, the at least one modifier is chosen from the group consisting of Co, Mn, Al, Fe, and Cu and the total mass of the at least one modifier element is less than 25 atomic percent of the final composition. Most preferably, the total mass of said at least one modifier element is less than 20 atomic percent of the final composition.

An example of a Ca—Ni based battery alloy is disclosed in U.S. Pat. No. 6,524,745 the disclosure of which is incorporated herein by reference. This patent discloses electrochemically stabilized Ca—Ni hydrogen storage alloy material for use as the active negative electrode material of an alkaline electrochemical cell. The alloy material includes at least one modifier element which stabilizes the alloy material from degradation during electrochemical cycling in an alkaline cell, by protecting calcium within the alloy and preventing dissolution of calcium into the alkaline electrolyte. The alloy has the formula (Ca_{1-x-y}MₓNi_{2y})Ni_{5-z}Q_{z}, where M is at least one element selected from the group consisting of misch metal, rare earth metals, zirconium and mixtures of Zr with Ti or V, Q is at least one element selected form the group consisting of Si, Al, Ge, Sn, In, Cu, Zn, Co, and mixtures thereof, x ranges between about 0.02 and 0.2, y ranges between about 0.02 and 0.4, and z ranges from about 0.05 to about 1.00.

Additionally, and in contradistinction to typical aqueous electrolyte metal hydride batteries, the batteries of the present invention have the distinct ability to use hydrogen storage materials which do not contain large quantities of anti-corrosive elements. That is, in aqueous electrolyte batteries, the metal hydride active material must contain significant amounts of elements such as nickel which protected the alloy from corrosion due to reaction of the remainder of the storage materials elements with the water in the presence of the electrolyte to permanently reduced and/or destroy the storage capacity of the active material. Thus, since the electrolyte of the present invention does not contain water in any significant quantities, the hydrogen storage alloys may significantly reduce or eliminate anti-corrosion elements, thereby significantly increasing the storage capacity of the alloy. Such alloys include but are not limited to alloys known for thermal gas phase storage of hydrogen. Any such gas phase alloy could be used, examples of some are listed hereinafter.

One such thermal alloy system is described in U.S. Pat. No. 6,746,645, the disclosure of which is hereby incorporated by reference. This patent describes alloys which contain greater than about 90 weight % magnesium and have 1) a thermal hydrogen storage capacity of at least 6 weight %; 2) thermal absorption kinetics such that the alloy powder absorbs 80% of it's total capacity within 10 minutes at 300.degree. C.; and 3) a gas phase cycle life of at least 500 cycles without loss of capacity or kinetics. Modifier elements added to the magnesium to produce the alloys mainly include Ni and Mm (misch metal) and can also include additional elements such as Al, Y and Si. Thus the alloys will typically contain 0.5-2.5 weight % nickel and about 1.0-4.0 weight % Mm (predominantly contains Ce and La and Pr). The alloy may also contain one or more of 3-7 weight % Al, 0.1-1.5 weight % Y and 0.3-1.5 weight % silicon.

Another type of gas phase alloy which can be used in the batteries of the present invention is disclosed in U.S. Pat. Nos. 6,737,194 and 6,517,970 the disclosures of which are hereby incorporated by reference. Generally the alloys comprise titanium, zirconium, vanadium, chromium, and manganese. The alloy may preferably further comprise iron and aluminum and may also contain 1-10 at. % total of at least one element selected from the group consisting of Ba, Co, Cu, Cs, K, Li, Mm, Mo, Na, Nb, Ni, Rb, Ta, Tl, and W (where Mm is misch metal). Specifically the low temperature hydrogen storage alloy comprises 0.5-10 at. % Zr, 29-35 at. % Ti, 10-15 at. % V, 13-20 at. % Cr, 32-38 at. % Mn, 1.5-3.0 at. % Fe, and 0.05-0.5 at. % Al. The alloy remains non-pyrophoric upon exposure to ambient atmosphere even after 400 hydrogen charge/discharge cycles, and preferably even after 1100 hydrogen charge/discharge cycles. The alloy has a gas phase thermal hydrogen storage capacity of at least 1.5 weight percent, more preferably at least 1.8 weight percent, and most preferably at least 1.9 weight percent.

Yet another gas phase hydrogen storage alloy that would be useful in the batteries of the instant invention are described in 6,726,783, the disclosure of which is hereby incorporated by reference. Disclosed therein is a magnesium-based hydrogen storage alloy powder. The alloy has a high hydrogen storage capacity, fast gas phase hydrogen adsorption kinetics and a long cycle life. The alloy is characterized in that it has an intergranular phase which prevents sintering of the alloy particles during high temperature hydriding/dehydriding thereof, thus allowing for a long cycle life. The magnesium-based hydrogen storage alloy powder comprises at least 90 weight % magnesium, and has: a) a hydrogen storage capacity of at least 6 weight % (preferably at least 6.9 wt %); b) absorption kinetics such that the alloy powder absorbs 80% of it's total capacity within 5 minutes at 300° C. (preferably within 1.5 minutes); and c) a particle size range of between 30 and 70 microns. The alloy also includes Ni and Mm (misch metal) and can also include additional elements such as Al, Y, B. C and Si. Thus the alloys will typically contain 0.5-2.5 weight % nickel and about 1.0-5.5 weight % Mm (predominantly contains Ce, La, Pr and Nd). The alloy may also contain one or more of: 3-7 weight % Al; 0.1-1.5 weight % Y; 0.1-3.0 weight % B; 0.1-3.0 weight % C; and 0.3-2.5 weight % silicon. The alloy is preferably produced via atomization (such as inert gas atomization), a rapid solidification process in which the quench rate is controlled to be between 10³-10⁴ °C/s.

A further gas phase hydrogen storage alloy which is useful in the batteries of the instant invention is described in U.S. Pat. No. 6,536,487, the disclosure of which is incorporated herein by reference. The alloys are atomically engineered hydrogen storage alloys having extended storage capacity at high pressures and high pressure hydrogen storage units containing variable amounts thereof. Specifically the hydrogen storage alloy is an alloy is an AB₂ alloy, such as a modified Ti—Mn₂ alloy comprising, in atomic percent 2-5% Zr, 26-33% Ti, 7-13% V, 8-20% Cr, 36-42% Mn; and at least one element selected from the group consisting of 1-6% Ni, 2-6% Fe and 0.1-2% Al. The alloy may further contain up to 1 atomic percent Misch metal. Examples of such alloys include in atomic percent: 1) 3.63% Zr, 29.8% Ti, 8.82% V, 9.85% Cr, 39.5% Mn, 2.0% Ni, 5.0% Fe, 1.0% Al, and 0.4% Misch metal; 2) 3.6% Zr, 29.0% Ti, 8.9% V, 10.1% Cr, 40.1% Mn, 2.0% Ni, 5.1% Fe, and 1.2% Al; 3) 3.6% Zr, 28.3% Ti, 8.8% V, 10.0% Cr, 40.7% Mn, 1.9% Ni, 5.1% Fe, and 1.6% Al; and 4) 1% Zr, 33% Ti, 12.54% V, 15% Cr, 36% Mn, 2.25% Fe, and 0.21% Al.

Still another traditionally gas phase alloy is disclosed in U.S. Pat. Nos. 6,491,866 and 6,193,929, the disclosures of which is herein incorporated by reference. The alloy contains greater than about 90 weight % magnesium and has a) a hydrogen storage capacity of at least 6 weight %; b) absorption kinetics such that the alloy powder absorbs 80% of it's total capacity within 10 minutes at 300° C.; c) a cycle life of at least 500 cycles without loss of capacity or kinetics. Modifier elements added to the magnesium to produce the alloys mainly include Ni and Mm (misch metal) and can also include additional elements such as Al, Y and Si. Thus the alloys will typically contain 0.5-2.5 weight % nickel and about 1.0-4.0 weight % Mm (predominantly contains Ce and La and Pr). The alloy may also contain one or more of 3-7 weight % Al, 0.1-1.5 weight % Y and 0.3-1.5 weight % silicon.

One final example of a useful magnesium based alloy is described in U.S. Pat. No. 6,328,821, the disclosure of which is herein incorporated by reference. The alloys have comparable bond energies and plateau pressures to Mg₂Ni alloys, while reducing the amount of incorporated nickel by 25-30 atomic %. This reduced nickel content greatly reduces cost of the alloy. Also, while the kinetics of the alloy are improved over pure Mg, the storage capacity of the alloy is significantly greater than the 3.6 wt. % of Mg₂Ni material. In general the alloys contain greater than about 85 atomic percent magnesium, about 2-8 atomic percent nickel, about 0.5-5 atomic percent aluminum and about 2-7 atomic percent rare earth metals, and mixtures of rare earth metals with calcium. The rare earth elements may be Misch metal and may predominantly contain Ce and La. The alloy may also contain about 0.5-5 atomic percent silicon.

The negative electrode may be a pasted electrode or may be a compacted electrode formed by either pasting or compressing the hydrogen storage material onto the conductive substrate. Generally, the conductive substrate may be selected from mesh, grid, matte, foil, foam, plate, and combinations thereof. Preferably, the conductive substrate used for the negative electrode is a mesh or grid. The porous metal substrate may be formed from one or more materials selected from copper, copper alloy, nickel coated with copper, nickel coated with copper alloy, and mixtures thereof. Preferably, the porous metal substrate is formed from copper or copper alloy. The negative electrode may also be wetted with water or an alkaline electrolyte, such as potassium hydroxide, prior to being incorporated into the sealed cell to increase ionic conductivity throughout the cell. Additionally the negative electrode may be electrochemically activated in a KOH solution prior to insertion into the battery.

The positive electrode comprises a positive electrode active material supported on a conductive substrate. The positive electrode active material may comprise a nickel hydroxide active material. The positive electrode may be a sintered type electrode or a non-sintered type electrode, wherein non-sintered electrodes include pasted electrodes. Generally, a pasted positive electrode can be formed by applying a powdered active material into the conductive substrate. The powdered active may be applied onto the conductive substrate via a pasting or compression technique. The positive electrode may also include a conductive polymeric binder as disclosed in U.S. patent Ser. No. 10/329,221, which has been previously incorporated by reference.

For example, nickel hydroxide positive electrodes are described in U.S. Pat. Nos. 5,344,728 and 5,348,822 (which describe stabilized disordered positive electrode materials) and U.S. Pat. No. 5,569,563 and U.S. Pat. No. 5,567,549 the disclosures of which are incorporated by reference.

Alternatively the positive electrode may be formed from other known positive electrode materials such as hydroxides, ferrates, manganates, chromates, cerates, oxalates as well as oxides. Specific examples of such materials include manganese hydroxide, cobalt hydroxide, lanthanum, barium hydroxide, calcium hydroxide, magnesium hydroxide, aluminum hydroxide, strontium hydroxide, barium ferrate, potassium ferrate, lithium ferrate, sodium ferrate, sodium manganate, lithium manganate, potassium manganate, potassium chromate, lithium chromate, sodium chromate, potassium cerate, lithium cerate, and sodium cerate. Other materials such as oxalates, oxides and mixed valency materials are also useful.

When forming the positive electrode, the positive electrode active material is prepared and affixed to a conductive substrate. Additive materials may be chemically impregnated into the active material, mechanically mixed with the active material, co-precipitated into or onto the surface of the active material from a precursor, distributed throughout the active material via ultrasonic homogenation, deposited onto the active material via decomposition techniques, or coated onto the active material. The positive electrode active material may be formed into a paste, powder, or ribbon. The positive electrode active material may also be pressed onto the conductive substrate grid to promote additional stability throughout the electrode. The conductive substrate may be selected from, but not limited to, an electrically conductive mesh, grid, foam, expanded metal, perforated metal, or combination thereof. The conductive substrates may be formed from copper, a copper alloy, nickel, or nickel coated with copper or a copper alloy. The positive electrode may also be wetted with water or an alkaline electrolyte, such as potassium hydroxide, prior to being incorporated into the sealed cell to increase conductivity throughout the cell. Additionally the positive electrode may be electrochemically activated in a KOH solution prior to insertion into the battery.

The anionic exchange membrane generally comprises one or more materials allowing the flow of hydroxyl ions therethrough. The anionic exchange membrane may be a specially designed cross-linked plastic material. The anionic exchange membrane may have a rigid or flexible structure which may provide support within each sealed cell. The anionic exchange membrane may be comprised of a polystyrene-divinylbenzene-polyvinylchloride polymeric material. The anionic exchange membrane preferably has a low ionic resistance and a high electrical resistance. The anionic exchange membrane may also require wetting prior to use to promote the transfer of hydroxyl ions therethrough. The wetting may be performed by dipping or boiling the anionic exchange membrane in a hydroxyl ion containing liquid like water or a compatible electrolyte, such as potassium hydroxide, prior to being incorporated into the sealed cell.

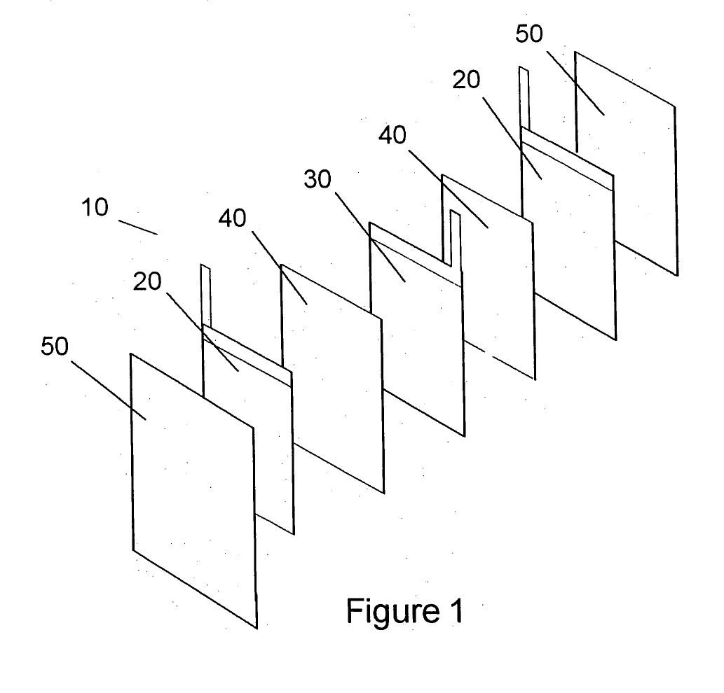

In a preferred embodiment of the present invention there is provided a solid state nickel metal hydride battery. An exploded view of the solid state electrochemical cell is depicted in FIG. 1. The solid state nickel metal hydride battery comprises a sealed electrochemical cell 10 including two negative electrodes 20, a positive electrode 30, and two anionic exchange membranes 40. The anionic exchange membranes are disposed on opposites sides of the positive electrode 30 thereby separating and remaining in contact with the positive electrode 30 and each negative electrode 20. The negative electrodes 20, positive electrode 30, and anionic exchange membranes 40 are then sealed between two thin plastic sheets 50 to complete the cell. Alternatively, the electrodes and the anionic exchange membranes may be sealed in a thin housing. The thin housing may be formed around the electrodes via various injection molding or overmolding processes to provide a sealed electrochemical cell.

The size of the solid state battery can be varied as required by the desired voltage, energy and power output of the battery. Two or more solid state batteries may also be connected in series based on the required voltage output. The solid state nickel metal hydride battery is lightweight and durable providing versatility for a number of applications. The solid state battery may also be rigid or flexible depending on the desired application.

Battery Example

A solid state nickel metal hydride cell in accordance with the present invention was constructed and tested for charge/discharge performance and cycle life performance. The solid state nickel metal hydride cell includes a standard positive electrode and two standard negative electrodes. Each negative electrode Was separated from the positive electrode by an anionic exchange membrane in contact with both the positive and negative electrode. The anionic exchange membrane was formed from Neosepta® AHA anion-exchange membrane (Registered Trademark of Tokuyama Corporation). To construct each cell, the positive electrode, the negative electrodes, and the anionic exchange membrane were stacked and sealed between two thin plastic sheets. Prior to forming the cell, each positive electrode was dipped in water to prevent any potential dissolution of CoO additive in potassium hydroxide and each negative electrode was electrochemically activated in a potassium hydroxide solution to wet the bulk of the negative electrode and to promote reactivity of the bulk of the negative electrode active material. The anionic exchange membrane was treated in a potassium hydroxide solution to promote the transfer of hydroxyl ions therethrough.

To form the standard positive electrode, a standard positive electrode paste was formed from 87.93 weight percent nickel hydroxide material with co-precipitated zinc and cobalt from Tanaka Chemical Company, 4.9 weight percent cobalt, 5.9 weight percent cobalt oxide, and 0.97 weight percent polytetrafluoroethylene, and 0.3 weight percent carboxymethyl cellulose (CMC). The paste was then affixed to a conductive substrate to form the standard positive electrode and electrochemically activated in a potassium hydroxide solution.

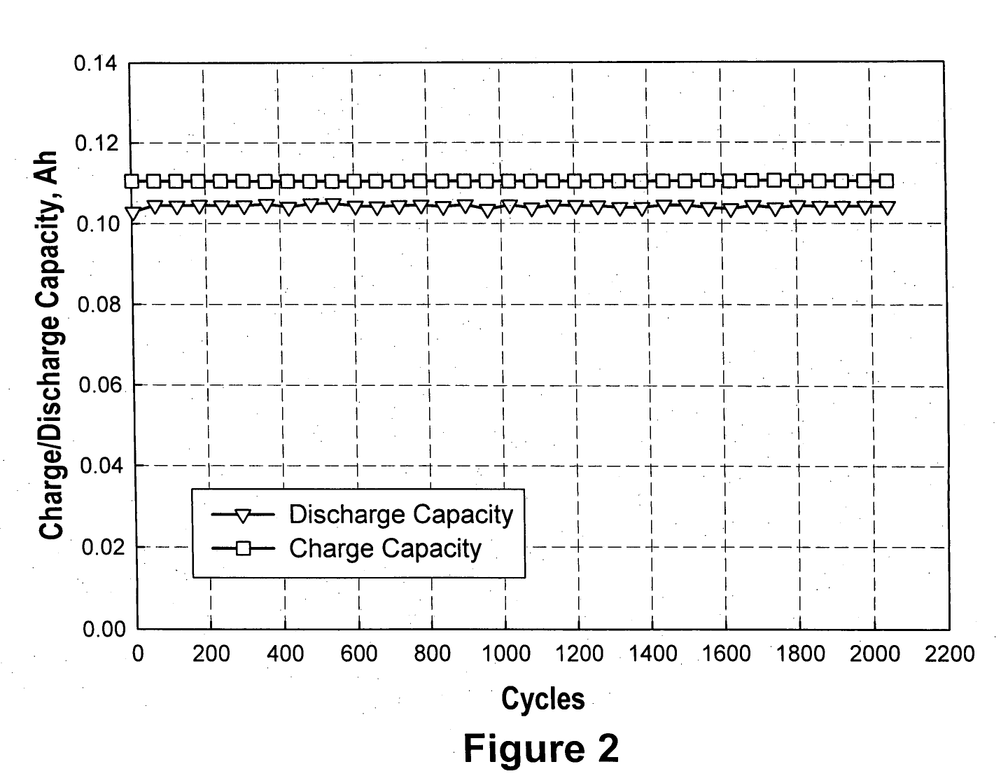

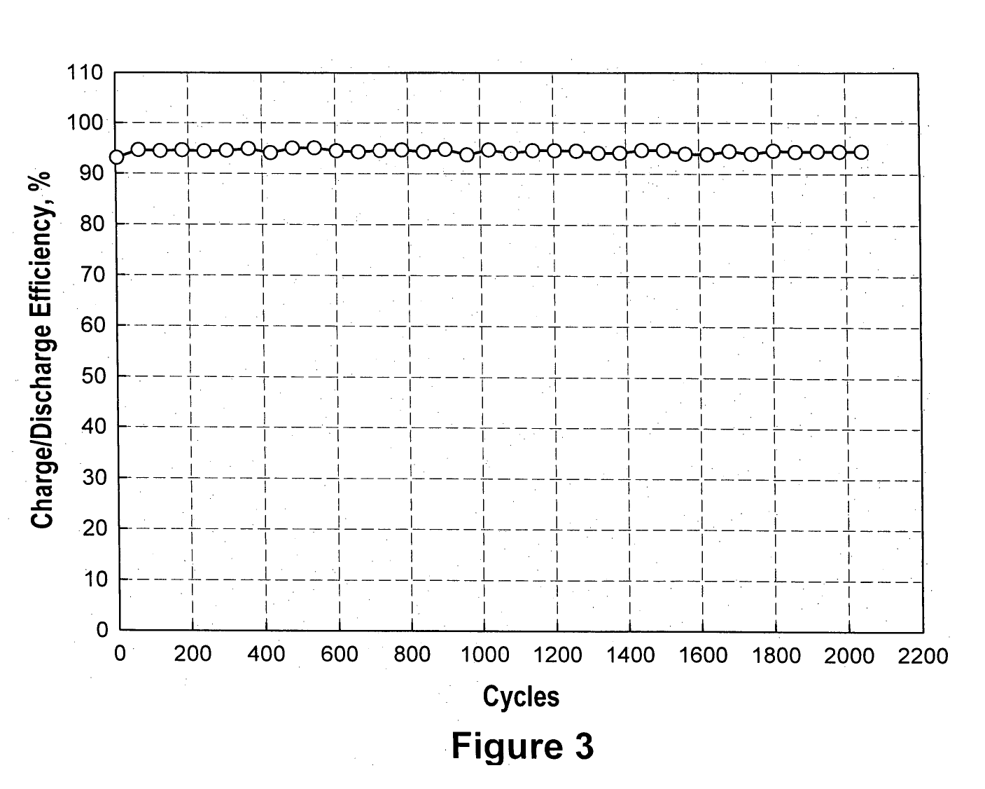

To form the standard negative electrode, a standard negative electrode paste was formed from 97.44 weight percent of an AB₅ hydrogen storage alloy, 0.49 weight percent carbon black, 0.49 weight percent polyacrylic salt, 0.12 weight percent carboxymethylcellulose, and 1.46 weight percent polytetrafluoroethylene. The composition of the AB₅ alloy was: MmNi_{3.66}Mn_{0.36}Al_{0.28}, where Mm is misch metal. The paste was then affixed to a conductive substrate to form the standard negative electrode. The charge/discharge capacity of the solid state electrochemical cell at a constant current of 320 mA (c/2) as a function of time is shown in FIG. 2 and the cycle life of the solid state electrochemical cell is shown in FIG. 3. Significantly it should be noted that this electrochemical cell has been cycled (at 20% state of charge) for over 2000 cycles.

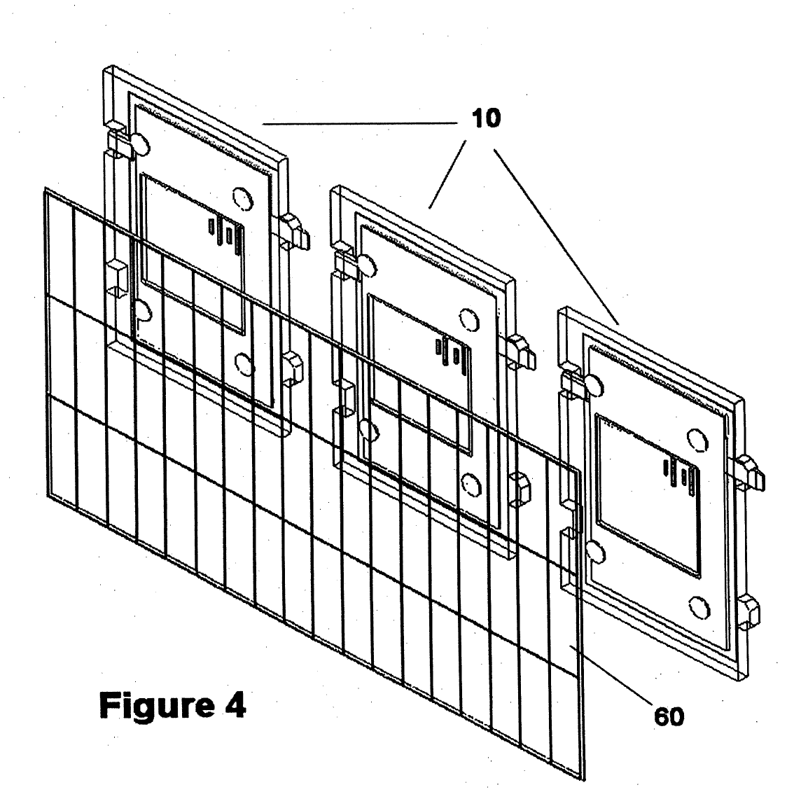

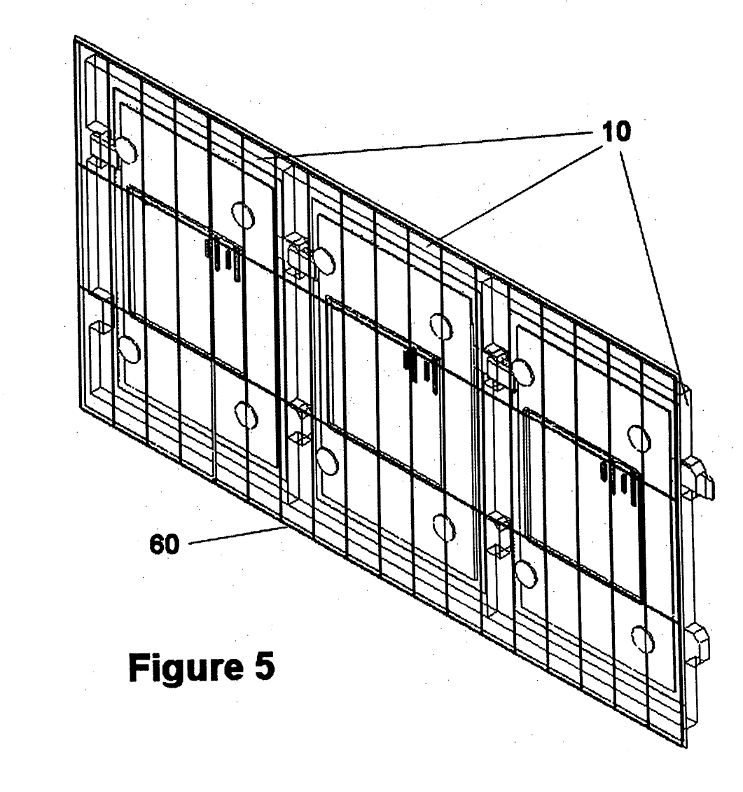

The solar cell of the present invention can be any of the known photovoltaic devices and can include amorphous, nanocrystaline, microcrystaline and single crystal solar cells. Amorphous silicon solar cells are the preferred photovoltaic devices, with the triple junction amorphous silicon solar cells of Stanford R. Ovshinsky being most preferred. Specifics on such triple junction amorphous silicon solar cells can be found in U.S. Pat. Nos. 4,891,074; 4,816,082; and 4,342,044, the disclosures of which are hereby incorporated by reference. FIGS. 4 and 5 depict a combination of solar cell and batteries of the present invention. Specifically, FIG. 4 shows a solar cell 60 and solid state batteries of the present invention 10 before they are combined. FIG. 5 shows the solar cell 60, preferably an amorphous silicon triple junction solar cell having the solid state batteries attached to or laminated on the rear of the solar cell. Preferably the triple junction solar cell is deposited on a flexible substrate such as a thin web of stainless steel foil, or a polymer web such as Kapton.

While there have been described what are believed to be the preferred embodiments of the present invention, those skilled in the art will recognize that other and further changes and modifications may be made thereto without departing from the spirit of the invention, and it is intended to claim all such changes and modifications as fall within the true scope of the invention.

1. A combined energy generation and energy storage system comprising:
a photovoltaic device; and
a solid state non-aqueous battery, comprising:
at least one negative electrode including a negative active material;
at least one positive electrode including a positive active material;
at least one anionic exchange membrane disposed between said negative electrode and said positive electrode.

2. The system of claim 1, wherein said positive active material is selected from the group of positive active materials consisting of hydroxides, ferrates, manganates, chromates, cerates, oxalates and oxides.

3. The system of claim 2, wherein said positive active material is a hydroxide selected from the group consisting of nickel hydroxide, manganese hydroxide, cobalt hydroxide, lanthanum hydroxide, barium hydroxide, calcium hydroxide, magnesium hydroxide, aluminum hydroxide, strontium hydroxide

4. The system of claim 3, wherein said positive active material is nickel hydroxide.

5. The system of claim 2, wherein said positive active material is a ferrate selected from the group consisting of barium ferrate, potassium ferrate, lithium ferrate, and sodium ferrate.

6. The system of claim 2, wherein said positive active material is a manganate selected from the group consisting of sodium manganate, lithium manganate, and potassium manganate.

7. The system of claim 2, wherein said positive active material is a chromate selected from the group consisting of, potassium chromate, lithium chromate, and sodium chromate.

8. The system of claim 2, wherein said positive active material is a cerate selected from the group consisting of, potassium cerate, lithium cerate, and sodium cerate.

9. The system of claim 1, wherein said negative active material is a metal hydride active material selected form the group of electrochemical hydrogen storage alloys and gas phase hydrogen storage alloys.

10. The system of claim 9, wherein said metal hydride active material is an electrochemical hydrogen storage alloy.

11. The system of claim 10, wherein said electrochemical hydrogen storage alloy is selected from the group of electrochemical hydrogen storage alloys selected from AB, AB₂, AB₅, A₂B₇, Mg—Ni, and Ca—Ni alloys.

12. The system of claim 9, wherein said metal hydride active material is a thermal gas phase hydrogen storage alloys.

13. The system of claim 1, wherein said anionic exchange membrane is an OH— ion exchange membrane.

14. The system of claim 13, wherein said OH— ion exchange membrane is a polystyrene-divinylbenzene-polyvinylchloride polymeric material.

15. The system of claim 1, wherein said photovoltaic device is at least one solar cell.

16. The system of claim 15, wherein said at least one solar cell is an amorphous silicon solar cell.

17. The system of claim 16, wherein said amorphous silicon solar cell is a triple junction amorphous silicon solar cell.

18. The system of claim 15, wherein said solar cell is deposited onto a polymer substrate.

19. The system of claim 1, wherein said solid state non-aqueous battery is laminated to the back side of said photovoltaic device.
